(19) United States
(12) Patent Application Publication
(10) Pub. No.: US 2006/0120171 A1
(43) Pub. Date: Jun. 8, 2006

(54) Seamless handoff of mobile terminal

(76) Inventors: Samy Touati, Rosemere (CA); Lila Madour, Kirkland (CA)

Correspondence Address: Sandra Beauchesne;Ericsson Canada Inc., Patent Department, 8400 Decarie Blvd., Town Mount Royal, QC, H4P 2N2, CA

(21) Appl. No.: 11/217,595

(22) Filed: Sep. 2, 2005

Related U.S. Application Data
(60) Provisional application No. 60/626,945, filed on Nov. 12, 2004.

(51) Int. Cl. G11C 7/10

(52) U.S. Cl. 365/189.05

(57) ABSTRACT

The invention relates to a solution for providing a seamless handover. It is proposed to provide a first serving node (PDSN) in a first radio area and a second serving node (WSN) in a second radio area and an authentication unit being accessible by the first serving node and by the second serving node. Further it is proposed to run a delay timer for delaying a discarding of the first address by receiving a detach message from the user for detaching from the first serving node and to provide said address to the user located in the second radio area in case a handover procedure has been performed within the duration of the timer.

### BACKGROUND OF THE INVENTION

1. Field of the Invention

The invention relates to performing a handoff of a mobile terminal between different technologies, in particular between WLAN and a 3^{rd} Generation (3G) mobile telecommunications network.

2. Description of the Related Art

Third Generation (3G) Networks such as CDMA 2000 and UMTS (Universal Telecommunication Network) provide high-speed wireless Internet access to mobile users over a wide coverage area. At the same time, Wireless Local-Area Networks (WLAN) based on technologies such as IEEE 802.11 or European HiperLAN provide low-cost, high-speed wireless Internet access solution within small areas.

In the following simplified network architectures of CDMA2000 and WLAN in respect to FIG. 1 are presented to explain the problem of interoperability between the different technologies. In particular the nodes being involved in provision of data service, like for example Internet files, to a mobile terminal are depicted.

A WLAN, 101, comprises, at least logically, an Access Point, AP 17, and a local area network gateway like for example a Wireless Service Node, WSN 18. According to FIG. 1 there is also a user with a Mobile Station, MS 11 being attached to the WLAN network. The Mobile Station (MS) might be a laptop, a palmtop or a phone that can access network. Herein it is to be ensured that the Mobile Terminal, MS11 supports both technologies, namely the WLAN and the 3G technologies. The Access Point AP 17 provides radio interface for users in a cell being served by said AP. Further it coordinates communication between numbers of users by means of multiple access protocols and it interfaces the cell to a WSN 18 and therefore implements differently layered packet forwarding functions. A local area gateway, like the WSN 18 provides connectivity to external networks, like for example to the Internet and/or to a 3G network. In FIG. 1 a direct link to the Internet is depicted. However this should not be seen as any restriction. There are existing solutions, in which the WLAN is integrated in the 3G technologies with a local gateway communicating with a 3G core network switches such as the PDSN in the CDMA2000 network. Independent on the connectivity, the local area gateway provides mechanisms and protocols handling at least authentification and mobility of the user.

A CDMA2000 packet switched network, 100 comprises, at least logically, a Home Agent HA 15, a Foreign Agent FA 16, a Packet Data Serving Node PDSN 13. A Packet Core Function (PCF) usually co-located with a Base Station Controller (BSC) builds in CDMA2000 a radio network node RN 12. Further there is an Authentication, Authorization and Accounting Server AAA 14 and in this particular case a user with a Mobile Station MS 11 being attached to the network. The Mobile Station MS 11 might be a laptop, a palmtop or a phone that can access both technologies, namely the WLAN and the 3G technologies. The BSC, among other things, establishes the traffic channel for the MS, coordinates the access for multiple users. The PCF is responsible, among other things, for deciding which PDSN to send the traffic through. The PDSN aggregates data traffic from multiple BS/PCFs. Further it terminates a Point-to-Point (PPP) connection and maintains session state for each MS in its serving area.

It is well known, that there are two modes of data provision by means of IP connectivity, namely Simple IP and Mobile-IP. In case of Simple-IP if a MS moves from one PDSN to another, a new IP address is acquired and the PPP connection between the MS and the PDSN is to be re-established, which consequently means a re-establishment of all running data sessions. The Mobile IP has been developed to seamless mobility solutions among the diversity of accesses by keeping the same IP address for a session whilst a user moves between PDSNs or even different systems. The Mobile IP defines a Home Agent HA as the anchor point with which the mobile user always has a relationship, wherein the Foreign Agent FA acts as the local tunnel-endpoint at the access network which the mobile user is visiting. Expressed somewhat differently, the HA provides mobile IP services and keeps track of the MSs association with a visited network and with an IP address of an ongoing session. Again, in other words, the HA assigns an IP-address to a MS for a particular data session, if a MS roams in another network or to another PDSN, then it establishes a new PPP connection to the new FA using however the old IP address, which is provided by the HA. Subsequently the HA performs a reallocation of the old IP address to the new FA in an internal entries so that if receiving packets intended for the MS a tunneling of said data packets is performed via the new FA in the network where the MS is located using the relation of the new FA and the IP-address.

Returning to FIG. 1 there is an authentication unit, namely the AAA server 14 communicating with the HA 15 and with the PDSN 13 and typically located in the home network. The home AAA administrates all user related data, like for example authentification information, such as secret keys, profile information, such as class of service, minimum bandwidth, or accounting information. This AAA account is being used for Mobile IP to provide authentication service for a roaming user while issuing a single billing statement.

In case of interoperation with CDMA2000 the WSN located in WLAN and supporting Mobile IP functionality implements an AAA service to interwork with the home AAA server in a 3G network. This enables to authenticate a user being in a WLAN for accessing a service and to collect accounting records generated in the WLAN.

Thus, the current development of the futures network goes into combining of both types of networks to provide ubiquitous high-speed wireless Internet connectivity to mobile users. In particular in such environment a need arises to provide a seamlessly switch between the complementary WLAN and 3G network, even during an ongoing Internet session. Mobile terminals that combine different radio interfaces in one device are already available. Further, there are solutions for seamless handover using Mobile IP. However, Mobile IP suffers from the problems of complex network architecture. First of all the Home Agent and the Foreign Agent are to be implemented in the network. This leads to a complex routing, since the packets are to be routed to a Home Agent and further to a Foreign Agent in a PDSN, which also has the task to route the data packets towards the users. Moreover the utilization of the Mobile IP leads to high handover latency, which even might end up in the range of 10 sec. Further, the implementation of the Mobile IP leads to large overhead of tunnelling IP packets, since the data packets are to be encapsulated for every link on the way from Service provider via the Home Agent, the Foreign Agent to the Mobile Station.

On the other hand the Simple IP as described above does not require the implementation of HA and FA. However, it has the disadvantage of assigning a new IP addresses and consequently of termination of an ongoing data session, which in case of file downloading means the necessity of re-loading the entire data file.

Even though in the above description, an interoperation between CDMA2000 and WLAN is described, it is to be pointed out that the same problems also occur in other 3G networks like in UMTS. Although, in UMTS different nodes are implemented, there is a relation in the provided functionality. Thus, for example the functionality implemented in a Serving GPRS Signalling Node (SGSN) and in a Gateway GPRS Signalling Node (GGSN) might be compared with the functionality of the PDSN node in CDMA2000 providing a serving of a user's session in a corresponding serving area. Further UMTS provides also an authentication unit, like the AAA server.

Further the same problems might also occur within one network, if there are different nodes serving a user in a way that the user has to establish a new connection if changing the serving nodes.

### SUMMARY OF THE INVENTION

Therefore it is subject of the present invention to provide a solution for a seamless handover between a local area network and a wide area network while guaranteeing an optimized data provision in the networks.

It is therefore one broad object of this invention to provide for a user a seamless handover between a first serving node in a first radio area and a second serving node in a second radio area, wherein a user's data session is identified in the first radio area by means of a first address and wherein an authentication unit being accessible by the first serving node and by the second serving node is provided and wherein said method comprises the following steps being performed in the first serving node,
providing the first address and an address of the first serving node to the authentication node and,
receiving a detach message from the user for detaching from the first serving node,
running a delay timer for delaying a discarding of the first address, wherein a receipt of a request from the second serving node for providing the first address within a duration of the delay timer leads to sending the first address to the second serving node.

It is therefore another broad object of this invention to provide for a user a seamless handover between a first serving node in a first radio area and a second serving node in a second radio area, wherein a user's data session is identified in the first radio area by means of a first address and wherein an authentication unit being accessible by the first serving node and by the second serving node is provided and wherein said method comprises the following steps being performed in the second serving node,
receiving an attach message from the user for attaching to the second serving node and,
sending a request to the authentication unit for providing permission to access a data session and,
receiving as an answer an address of the second serving node from the authentication node and,
sending a request for the first address to the first serving node using the address of the second serving node and,
assigning the first address to the user's data session after receiving the first address.

It is therefore another broad object of this invention to provide a method for providing for a user a seamless handover between a first serving node in a first radio area and a second serving node in a second radio area, wherein a user's data session is identified in the first radio area by means of a first address and wherein an authentication unit being accessible by the first serving node and by the second serving node is provided and wherein said method comprises the following steps being performed in the authentication unit,
receiving the first address and an address of the first serving node from the first serving node and,
saving the first address and the address of the first serving node and,
receiving a request from the second serving node for providing permission to access a data session and,
sending as a response an address of the first serving node to the second serving node.

It is therefore another broad object of this invention to provide a first serving node for providing for a user a seamless handover between said first serving node in a first radio area and a second serving node in a second radio area, wherein a user's data session is identified in the first radio area by means of a first address and wherein an authentication unit being accessible by said first serving node and by the second serving node is provided and wherein said first serving node has,
sender unit for providing the first address and an address of said first serving node to the authentication node and,
receiver unit for receiving a detach message from the user for detaching from the first serving node,
delay timer for delaying a discarding of the first address, wherein a receipt of a request from the second serving node for providing the first address within a duration of the delay timer leads to sending the first address to the second serving node.

It is therefore another broad object of this invention to provide a second serving node for providing for a user a seamless handover between a first serving node in a first radio area and said second serving node in a second radio area, wherein a user's data session is identified in the first radio area by means of a first address and wherein an authentication unit being accessible by the first serving node and by the second serving node is provided and wherein said second serving node comprises,
a first receiver unit for receiving an attach message from the user for attaching to the second serving node and,
a first sender unit for sending a request to the authentication unit for providing permission to access a data session and,
a second receiver unit for receiving an address of the second serving node from the authentication node and,
a second sender unit for sending a request for the first address to the first serving node using the address of the second serving node and,
assignment unit for assigning the first address to the data session.
   It is therefore another broad object of this invention to provide an authentication unit for providing for a user a seamless handover between a first serving node in a first radio area and a second serving node in a second radio area, wherein a user's data session is identified in the first radio area by means of a first address and wherein said authentication unit being accessible by the first serving node and by the second serving node is provided and wherein said authentication unit comprises,
a first receiver unit for receiving the first address and an address of the first serving node from the first serving node and,
a storage unit for saving the first address and the address of the first serving node and,
a second receiver unit for receiving a request from the second serving node for providing permission to access a data session and,
a sender unit for sending the address of the first serving node to the second serving node.
   It is therefore another broad object of this invention to provide a network part for providing for a user a seamless handover between a first serving node in a first radio area and a second serving node in a second radio area, wherein a user's data session is identified in the first radio area by means of a first address and wherein an authentication unit being accessible by the first serving node and by the second serving node is provided and wherein said network part with,
the first serving node
   sending the first address and an address of the first serving node to the authentication node for storing said addresses and
   running a delay timer for delaying a discarding of the first address by receiving a detach message from the user for detaching from the first serving node
the second serving node
   sending a request to the authentication unit for providing a second address for user's data session by receiving an attach message from the user for attaching to the second serving node, and
   receiving the second address and an address of the second serving node from the authentication node, and
   sending a request for the first address to the first serving node using the address of the second serving node, and
   assigning the first address to the user's data session, if the first serving node has responded to the request by providing the first address or assigning the second address to the user's data session, if the first address is no available

### BRIEF DESCRIPTION OF THE DRAWINGS

In the following preferred examples of the present invention shall be described in detail, in order to provide the skilled person with thorough and complete understanding of the invention, but these detailed embodiments only serve as examples of the invention and are not intended to be limiting. The following description shall make reference to the enclosed drawings, in which

FIG. 1 shows a schematic representation of architecture of a network providing seamless handover according to prior art,

FIG. 2 shows a flowchart of an embodiment of the present invention for realizing seamless handover in a data session node,

FIG. 3 shows a flowchart of an embodiment of the present invention for realizing seamless handover in a local area network gateway,

FIG. 4 shows a flowchart of an embodiment of the present invention for realizing seamless handover in a authentication unit,

FIG. 5 shows a schematic representation of architecture of a network providing seamless handover according to the invention,

FIG. 6 shows a nodal operation and signal flow diagram illustrating a flow of messages in a wide area network according to the invention,

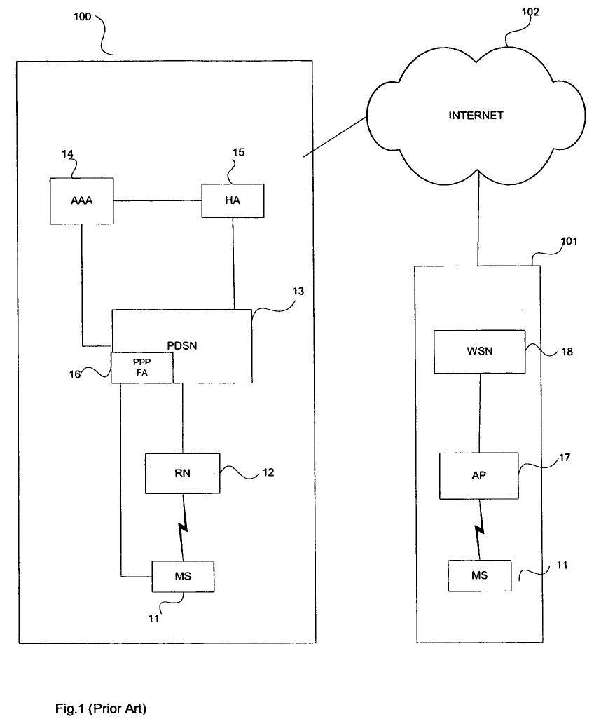

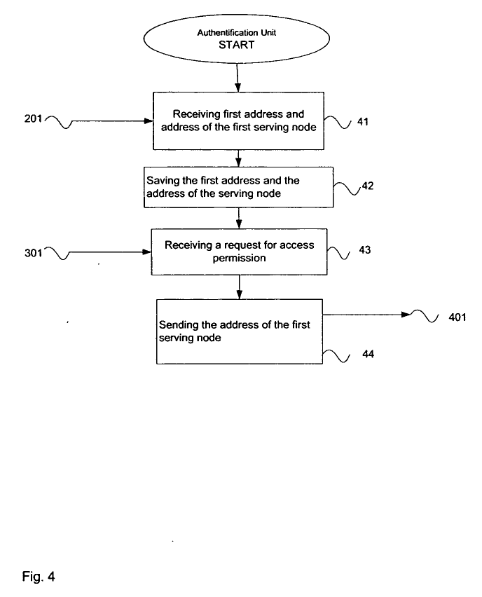

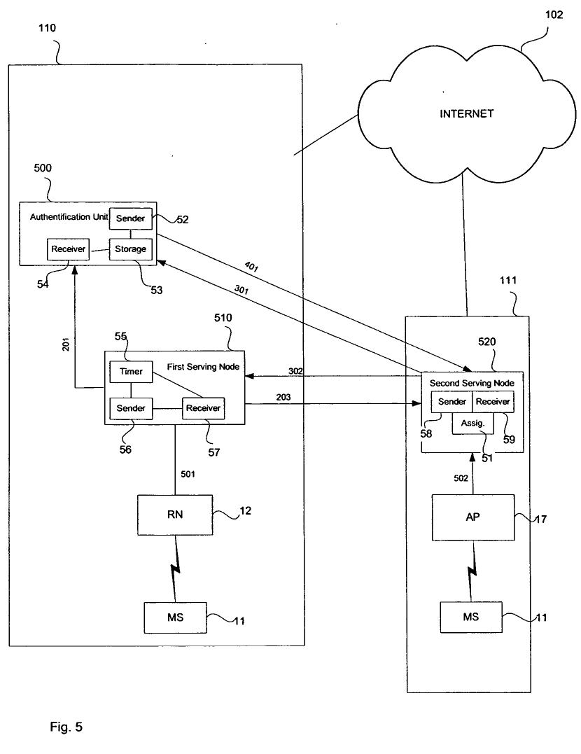

FIG. 4 shows a nodal operation and signal flow diagram illustrating a flow of messages in a local area network involving some functionality in a wide area network according to the invention.

### DETAILED DESCRIPTION OF THE PREFERRED EMBODIMENTS

It should be noted that the term “node”, “unit” in the context of the present invention refers to any suitable combination of hardware and software for providing a predetermined functionality in the communication network. In this way, said terms generally refers to a logical entity that can be spread out over several physical entities of the network, but can also refer to a physical entity located in one physical location.

It should be noted that the term “user” in the context of the present invention refers to a user equipment or a mobile station being a combination of hardware and software with the purpose to access a data session, to which an address is to be assigned in order to transmit data. Further no restriction should be made regarding whether it is one user or a multitude of users, which means that either one user might have one or a number of data sessions for which a seamless handover is to be performed, or the term might means a number of user's terminals with their sessions.

Further the first serving node and the second serving node refers to any combination of hardware and software for serving a user and his/hers data sessions. In CDMA2000, a PDCN node might perform the task of the first serving node. In case of UMTS, this task might be performed by a suitable combination of hardware and software being located in SGSN and GGSN.

Preferably the second serving node is located in a local area network, like for example the WLAN and the functionality might be implemented in any suitable gateway in said local network, like for example in the Wireless Service Node WSN in WLAN.

Preferably, the wide area communication network is a mobile communication network, e.g. is a mobile communication network operating according to CDMA2000 or UMTS (Universal Mobile Telephone System) or GPRS (General Packet Switched Radio) or any 3G system like for example EDGE, WCDMA. However, the present invention is also applicable in any communication network aiming to provide seamless handover without employing Mobile IP.

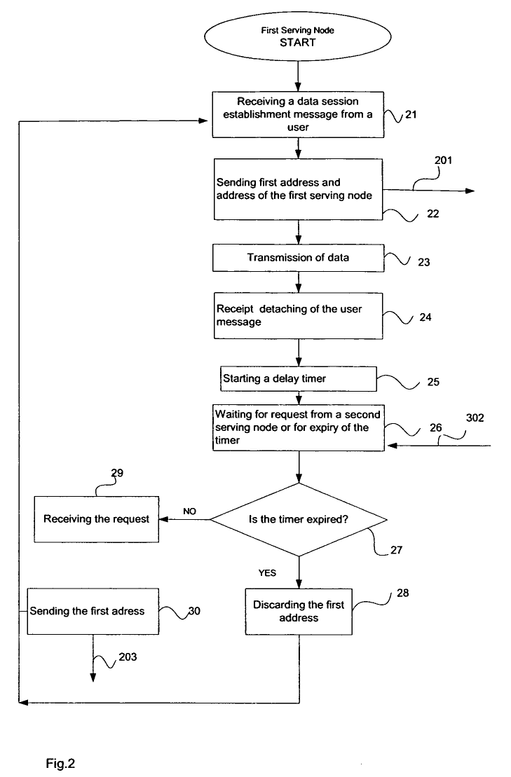

In the following an embodiment of the present invention in respect to FIG. 2 is given. FIG. 2 describes steps, which are to be performed on the first serving node according to the present invention.

It is proposed that the first serving node participates in a data session by receiving a data session establishment message from the user for the sake of simplicity. However the first serving node might be also implemented as a node being separated from the transmission of data, since the task of the first serving node is to assign the first address. This might be performed for example during the establishment phase of a data session for a user.

Therefore, according to FIG. 2, the first serving node receives a data session establishment message from the user, step 21. During this phase the first address, preferably an IP-address is assigned to the user establishing the session. Preferably the assignment of the IP-address is to be performed in the first serving node, during or after an authentication phase which is to be carried out to check user's credibility.

Upon the first address, like the IP-address is assigned to the user's data session, according to the present invention it is proposed to send the assigned first address and the address of the first serving node to the authentication node, step 22 by sending the message 201. The sending of the addresses might be performed in any suitable way, for example it might be either sent in one or in separate message(s). In a subsequent step, step 23, the first serving node is preferably included in the transmission of the data, which should not be seen as a limitation. The first serving node is to be informed about a user leaving its serving area, step 24. This might preferably be performed by receiving a detach message, which might be sent by the user or any entity in the network notifying that the user has left. Such kind of a detach message is required to start a delay timer, step 25.

Currently when receiving a detach message the first address is discarded, since this means the user is not anymore in the serving area. According to the present invention it is proposed to delay the discarding of the first address, being assigned to user for the duration of the delay timer. Said timer might be implemented in any suitable way providing counting for a set time value. The duration of the timer might be either set statically to a particular value, or it might be variable value. Some experiments have shown that a handover between different networks might last up to 60 sec, so this measured value might be taken as an example in case the method is implemented for an inter-networks handover. However this should not be seen as any limitation to the present invention.

Thus, according to the implementation of the timer, said timer runs unless one of the events occurs, namely either the timer expires or a request from a second serving node, the message 302, for providing the first address is received. If the checking procedure results in an expired timer, step 27, then the first address is discarded, step 28. If the occurred event is the receipt of the request, step 29, then the first address is sent back, step 30 and message 203. Thus, the provision of the first address is only possible if the timer has not expired yet. Preferably if a request from the second serving nodes arrives after the expiration of the timer, then a non-availability of the first address message might be issued to the second serving node. Another option might be that in this case the first serving node does not send any message and it is the responsibility of the second serving node to act accordingly.

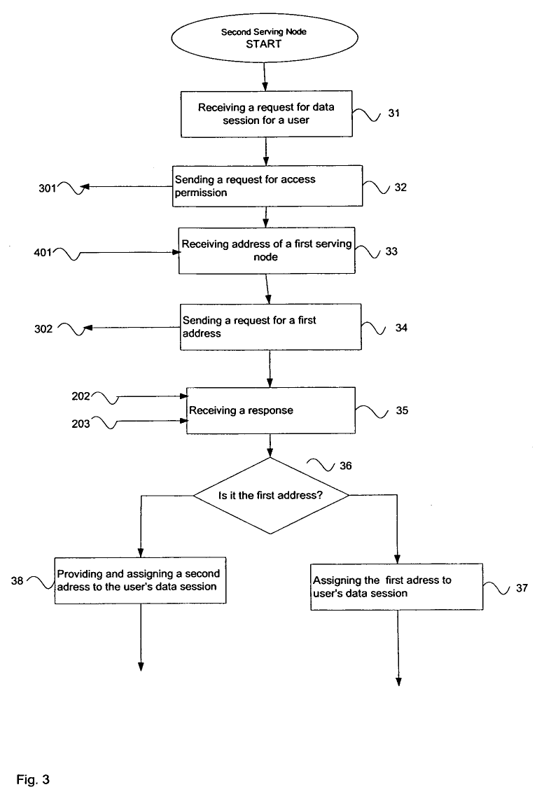

In the following an embodiment of the present invention in respect to FIG. 3 is given. FIG. 3 describes steps, which are to be performed on the second serving node according to the present invention.

As already mentioned, preferably the second serving node is a node being located in a second network with a different technology, like for example a Wireless Service Node WSN located in a WLAN.

A user coming to the second network has to attach to the serving area in said second network to establish a connection for transmission of data. Preferably the second serving node is involved in the communication. Therefore according to FIG. 3 it receives an establishment message to establish a connection to the user, step 31. In order to establish a data session the second serving node assigns an address to the user, preferably an IP-address. This is to be performed after permission is given to establish a connection to the user. Thus, in step 32 a request, message 301, is sent to the authentication unit for providing permission for accessing data session. According to the invention, as a result the second serving node receives with the message 401 an address of the first serving node, step 33, wherein the address of the first serving node is used to contact said first serving node to get the first address, step 34 message 302. The sending of the request might result in receiving a response, step 35. The response from the first serving node provides the first address if the request for the first address has been received by the first serving node within a duration of the delay timer being started on the first serving node, message 203. In case the request for the first address has not been received within the duration of the delay timer, preferably a non-availability of the first address message might be provided to the second serving node. However there might be other suitable solution for informing the second serving node about non-availability of the first address. For example, the second serving node might have also a timer and in case no response is received during the duration of this timer, it is assumed the first address can not be provided. Therefore it is proposed in step 36 to check whether the received response includes the first address, wherein this might be performed in any suitable way.

In case of having the first address, said address is assigned to the user's data session, step 37. Since the address has not changed while moving from a first radio network to a second radio network, the user might still access the same data session in a new network. Thus, the user experiences a seamless handover while changing networks. However, if the first address could not be provided, then a second address is assigned to the user, step 38, which means that in this case a session must be re-established. Preferably the second address is to be provided by the second serving node. There are different existing method for provision an address, like for example of IP-address a server might be contacted to assign a unique address or it might be taken form a local pool of addresses. Further it is to be noticed, that the provision of the second address might be performed at any time during the procedure according to FIG. 3.

In the following an embodiment of the present invention in respect to FIG. 4 is given. FIG. 4 describes steps, which are to be performed on the authentication unit according to the present invention.

According to FIG. 4 the authentication unit receives in step 41 the first address and the address of the first serving node with the message 201. In a subsequent step 42 said addresses are stored in any suitable way and in any preferably place. The steps 41 and 42 are performed while the user is in the first radio network, like for example in a wide area network, as the CDMA 2000 or the UMTS network. In case said user moves to a second radio network, like for example to WLAN, then the authentication unit receives a request for permission to access a data session. Said request is received from the second serving node, step 43, message 301. As a response the authentication unit sends according to the present invention the address of the first serving node, step 44, message 401. The answer might be generated in any suitable way, for example as a separate message or as a part of a message accepting the access.

In the following an embodiment of the present invention in respect to FIG. 5 is presented. FIG. 5 depicts schematic nodes and connections therebetween presenting a schematic architecture of a network providing seamless handover according to the invention. There is a first network, 110, and a second network, 111. The responsibility of the networks is to serve a user, MS 11, being currently located in one of said networks. Further there is Internet, 102 to provide data to the user, MS 11. However the provision of the Internet should not be seen as a restriction for the present invention, since different ways of providing data might be implemented, like for example there might be a server in one of the networks issued for the data provision purpose. As foregoing mentioned, an example of the first network might be a wide area network, like CDMA 2000 or UMTS and of the second network, local area network, like WLAN. In FIG. 5 the first and the second network are depicted as two separate network. However there might be also a solution, in which one network is integrated in another network, wherein both networks provide different not overlapping radio coverage. A further embodiment might be a network architecture with one network and a number of serving nodes, wherein for a user changing the serving node an address for providing data session is to be assigned. Therefore according to the present invention a general term, namely a first and a second radio area is used. In network architectures like described a seamless handover according to the present invention is applicable.

Returning to FIG. 5, the first network, 110, comprises an authentication unit, 500, a first serving node, 510, a first radio area, RN 12. The RN 12 provides a radio connection to the user MS, 11 being currently in its coverage area. In case said user, MS 11 moves to a second radio area, 111, then it is served by the radio access therein, according to FIG. 5 it is the access point AP 17. Furthermore the second radio area comprises a second serving node, 520.

The first serving node, 510, comprises a sender, 56, a receiver, 57 and a timer, 55. The components might be realised in any suitable and preferably way. Thus, they might be realised as hardware or software or any combination thereof. Furthermore they might be implemented as separate units or as one unit. The sender 56 provides a first address and an address of said first serving node to the authentication unit, 500, over the connection 201. The task of the receiver 57 is to receive a detach message from the user for detaching from the first serving node, 510. Said message is transferred over the radio connection and the connection depicted as 501. Further there is the timer, 55, for delaying a discarding of the first address as aforementioned.

The authentication unit, 500, comprises a sender, 52, a receiver, 54 and storage, 53. The components might be realised in any suitable and preferably way. Thus, they might be realised as hardware or software or any combination thereof. Furthermore they might be implemented as separate units or as one unit. In particular the receiver is foreseen to receive messages from the first serving node, 510, message 201 carrying the first address plus an address of the first serving node, and from the second serving node, message 301 carrying a request for providing a second address for a user's data session. Preferably both functions are to be implemented in one unit. Further there is also a storage unit, 53 for saving the first address and the address of the first serving node. The sender, 52 sends the messages 401 and 402, which might be implemented as one message carrying the second address and the address of the first serving node to the second serving node.

The second serving node, 520 has a sender, 58 with a function for sending the message 301 carrying a request for providing permission to access a data service and with a function for sending the message 302 carrying a request for providing the first address. A receiver, 59, is foreseen to receive an attach message from the user, MS 11, attaching to the second serving node over the message 502 and for receiving an address of the second serving node from the authentication node, message 401.

According to the present invention the first serving node, 510 sends a first address being assigned to an ongoing user data session and an address of the first serving node, 201 to the authentication node, 502 for storing said addresses in storage 53. Both addresses are to be preferably, IP addresses. After a detach message, 501 from the user is received a timer, 55 for delaying a discarding of the first address is started.

In case a user, MS 11 moves to a second radio network, 111 with the second serving node, 520. At first the MS 11 attaches to the network by means of a attach message, 502, and then the second serving node, 520 sends a request to the authentication unit 500 for providing permission to access a service, which might be performed for example during an authentication procedure. Upon receipt of this message, the authentication unit 500 provides an address of the second serving node, message 401. In the next step, the second serving node, 520 sends a request for the first address to the first serving node 510 by the aid of the received address of the second serving node, message 302. The first serving node, 510 receives the request and at first it checks whether the first address being assigned to the user's data session while having the user in its coverage are is still available, in other words, whether the delay timer has not expired at this point. In this case the first address is provided to the second serving node, 520, message 203. In case the second serving node has received the first address a seamless handover might be guaranteed by assigning the first address to the user's data session, which is performed in the assignment unit, Assig. 51. In order to provide a full functionality of the system it is proposed to assign the second address to the user's data session, in case the first address is not available, as it is known.

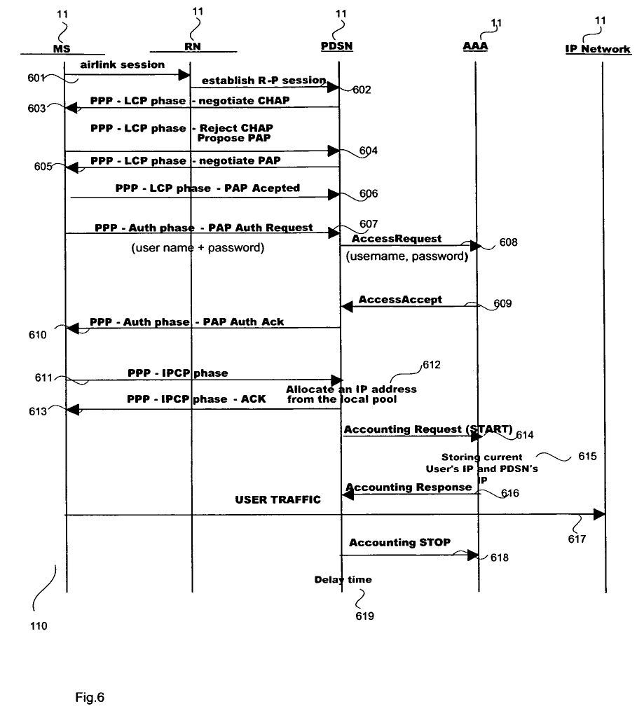

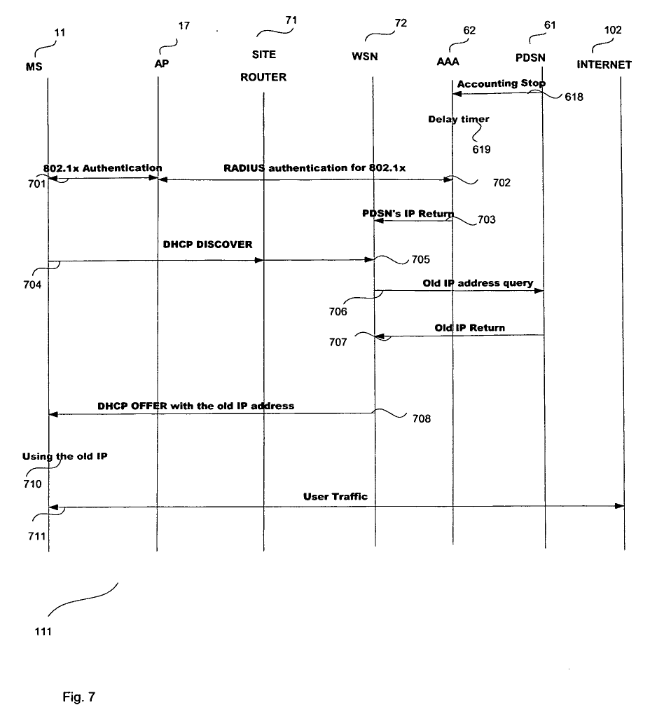

In the following an embodiment of the present invention is presented in respect to FIG. 6, which illustrates a nodal operation and signal flow diagram representing a flow of messages for a soft handover without MobileIP in a CDMA2000 network in accordance to the invention. The network, 110, comprises a Radio Network Part, 12, which might be represented for example by BS/PCF node, as described above. Further the network comprises a PDSN, 61 and a AAA node, 62. It is to be mentioned that in this example the PDSN, 61 corresponds to the first serving node 510 and the AAA is an embodiment of the authentication unit in CDMA2000. A Mobile Station, MS 11 is located in the serving area of the network 110 and is served by the RN 12 and the PDSN 61. Usually the MS is identified with a unique identity, like for example with an International Subscriber Identity (IMSI). However there might be different ways of implementing user's identity.

In FIG. 6 the MS 11 initiates an airlink session 601 to the RN 12, this might be performed by sending an attach message. Upon receiving an initiation message form the MS 11, the RN 12 establishes a R-P session (602). The R-P session is a logical connection established between the Radio Network (specifically the PCF) and the PDSN, in particular for providing a PPP session. The PDSN 61 initiates the establishment of a PPP connection by sending a PPP-LCP phase-negotiate CHAP message, 603. In the following the well-known establishment of a PPP connection is explained in more details.

The Point-to-Point Protocol (PPP) provides a standard method of encapsulating network layer protocol information over point-to-point links. PPP also defines an extensible Link Control Protocol (LCP). The Link Control Protocol (LCP) is utilized for establishing, configuring, and testing a data-link connection. Thus, each end of the PPP link sends at first LCP packets to configure the data link during Link Establishment phase for an optional Authentication phase before proceeding to the Network-Layer Protocol phase, during which data session is transmitted. Currently two protocols are utilized for Authentication, namely the Password Authentication Protocol PAP and the Challenge-Handshake Authentication Protocol CHAP. The Password Authentication Protocol (PAP) provides a simple method for a node to establish its identity by sending repeatedly the assigned identity/password pair until the authentication of said node is acknowledged or the connection is terminated. The Challenge-Handshake Authentication Protocol (CHAP) is used to periodically verify the identity of a node. This is done upon initial link establishment, and may be repeated anytime after the link has been established. Thus, there are different methods, which might be chosen to perform authentification during establishing of a PPP connection. Wherein in order to perform the authentification successfully the communicating nodes are to be configured accordingly, dependent on the chosen method.

Returning to FIG. 6, in step 603 the PDSN proposes to use CHAP for the authentification purpose. Obviously the MS 11 does not support said protocol since in step 604 a message carrying a rejection of CHAP and a proposal to use PAP is sent. As an answer the PDSN, 61, sends in step 605 a PPP-LCP phase-negotiate PAP message to the MS 11, which accepts it by sending a PAP accept message 606. Sending this message means a successful termination of the PPP-LCP phase.

In the subsequent message, step 607 the MS 11 sends a PAP authentification request carrying as parameter, as mentioned above a pair comprising the user name and the password. In this context it is to be mentioned, that the user name might be provided in any suitable and preferably way, depending on the implemented method in a network. Thus, it might be a NAI number, like for example the IMSI number. Further the authentification by means of PAP is to be seen as one possible embodiment without any limitation to the present invention. Thus, any other authentification method might be applied, or even since the authentification is not mandatory, the establishment phase might be performed without utilization of any authentification protocols. The user name is used for verification whether said user is permitted to access a service. Thus, in step 608 an Access Request, 608, message is sent to the AAA, 62, carrying the user name. In the server AAA a corresponding verification procedure is carried out, like for example the validation of the received password with the user as identified by the user name. In case of a successful verification, an Access Accept message is sent to the MS, 11, in step 609. The MS, 11, receives as an answer to the successful performed authentification, an acknowledgement message, PPP-Auth phase-PAP Auth Ack (610), sending of which means a termination of the authentification phase.

In the next phase, an establishment and a configuration of a IP connection for a data session is issued. Thus, in step 611 the MS, 11, sends a PPP-IPCP phase message to the PDSN, wherein IPCP is an abbreviation for PPP Internet Protocol Control Protocol and is used to establish and configure IP protocol over PPP. Upon receipt of this message, the PDSN, 61, allocates an IP address from the local pool, step 612, and assigns said IP address to the user name. In this context the IP address as just described is an embodiment of the first address as aforementioned. The user, MS, 11, receives a notification of a successful assignment of an IP address in form of an acknowledgment message, PPP-IPCP phase-ACK, 613 wherein said message carries the IP-address assigned to the user, MS 11. In the next step the PDSN 61 sends an accounting request, step 614, to the AAA, 62, for starting an accounting procedure for the following data session. Herein the present invention proposes to provide the AAA server, 62, with the first address, which is in this embodiment the assigned IP address and the IP address of the PDSN. Upon receiving the information the PDSN, 61 stores it in a suitable way, step 615. Preferably it is proposed to store this information in a user profile, which already exists on the AAA server. However it might be performed in any appropriate way, which ensures a reconstruction of the relation between the user name, the assigned IP address and the IP address of the PDSN node.

Subsequently the PDSN, 62 sends an accounting response to the MS 11, in step 616, whereupon the transmission of data session is started, step 617. In case the user moves to another network, or to another PDSN, which might be recognized by receiving a detach message from the user, MS 11, then an Accounting STOP message, 618, is sent from the old PDSN, 61, to the AAA, 62. According to the present invention it is proposed to start a delay timer, step 619 when the account STOP message is sent out. As already mentioned, this timer is used to delay the deleting of the IP-address assigned to a user's data session. Currently this message is being directly deleted after sending the Accounting stop message. According to the present invention, during the duration of the timer the PDSN waits for receiving any information on the location of the user, in other words it waits for receiving a message from the user who sent a detach message and who moved to another network. Thus, the deleting of the IP-address is delayed by the duration of the handover. In case no message from the new network serving the user is received in within the time interval, then upon expiration of the timer, the IP-address of the user's data session is discarded.

In the following an embodiment of the present invention is presented in respect to FIG. 7, which illustrates a nodal operation and signal flow diagram representing a flow of messages for a soft handover without MobileIP in a WLAN involving some functionality, namely PDSN and AAA located in CDMA2000 in accordance with the invention. The network, 111, comprises an Access Point AP 17, which is in case of the wireless user a radio network part in WLAN network. Further in respect to FIG. 7 there is a Site Router, 71, which represents a DHCP relay agent, as it is described below and a Wireless Service Network WSN, 72, which is an embodiment of a second serving node. As it is described further WSN includes also additional functionality, like the DHSP server functionality. In FIG. 7 also the AAA, 62 and the PDSN, 61 are depicted, as described in connection with FIG. 6. A mobile Station, 11 is located in the serving area of the network 111 with the aim to access the Internet 102.

For the sake of clarity and continuity, the last steps from FIG. 6 are repeated, namely the step 618, Accounting STOP and the step 619, Starting delay timer, in order to emphasize the state of the PDSN when the user, MS 11 starts a session establishment in WLAN. WLAN is usually based on the well-known IEEE 802.1 standard with the defined 802.1 protocols. According to the 802.1 framework, no network traffic is possible until the user is authenticated and this is performed by means of the 802.1x Authentification messages, in step 70. The AP, 17 does not hold a list of users, but sends the authentication request to an “authentication”-server, which is usually a Remote Authentication Dial-In User Service (RADIUS) server and in the present embodiment implemented on the AAA server, 62. Therefore, in step 702, a RADIUS authentification for 802.1x is sent. Although not depicted in FIG. 7 the IEEE 802.1x authentification comprises sending an Access-Request from the user, MS 11, to the RADIUS server, AAA, wherein said message carries among other attributes, an user name. Further it might carry passwords in order to validate user's credibility to access a service. However, it is to be pointed out, that there is a multitude of possible validation algorithms. Subsequently, as a response to the Access-Request message, the PDSN, 62 sends an Access-Accept or an Access-Reject towards the user, MS 11. In accordance with the present invention the AAA, 62, augments the Access-Accept message with the IP address of the PDSN and it is a task of the WSN to snoop on the message in order to capture said IP address of the PDSN. In this embodiment the IP address of the PDSN is automatically embodied in the response message during the authentication procedure. However, it should not be seen as any restriction to the present invention. It is also possible in this embodiment to request the IP address of the PDSN explicitly or to get it automatically in any suitable message.

Returning to FIG. 7, in step 703 the WSN receives the IP of the PDSN after the authentication phase is terminated. In the next step 704, which must not be a subsequent step to step 703, which might be the case if no authentication is performed, a DHCP DISCOVER message is sent to WSN, 72.

A Dynamic Host Configuration Protocol (DHCP) as it is well-known provides a framework for passing configuration information to users on Internet. DHCP adds the capability to automatically allocate reusable network addresses and configuration options to Internet users. DHCP consists of two components: a protocol for delivering user-specific configuration parameters from a DHCP server to a user and a mechanism for allocating network addresses to the users. A DHCP client is an Internet user using DHCP to obtain configuration parameters such as an IP address. In the present embodiment, the user, MS 11 is a DHCP client and the WSN, 72 fulfils the task of a DHCP server. In order to obtain an IP address the user, MS 11, sends a DHCP DISCOVER broadcast message, 704 to locate a DHCP server. Said broadcast message is intercepted by a relay agent, SITE ROUTER, 71, which forwards the packets between the user MS, 11 (DHCP client) and the WSN, 72, (DHCP server), step 705. The WSN (DHCP server), 72 offers configuration parameters such as an IP address to the user in a DHCP OFFER unicast message. According to the present invention before responding with the DHCP OFFER message, the WSN queries the PDSN, step 706, using the received PDSN IP address to get the old user's IP address being an embodiment of the first address, which the user has had in the previous network. As a result of the query the WSN receives an answer, wherein either said answer includes the old user's IP address or it carries an indication, that the user's IP address is not more available, step 707. The content of the answer message depends on a time point of receiving the query message. In case the query message is received within the duration of the delay timer, then an old IP-address is given back. However, if the timer has already expired, than the user's IP has been deleted, and only an indication of non-availability of the IP address is given back.

According to FIG. 7 it is assumed that the query has been performed within the delay timer, which results in sending a DHCP OFFER message carrying the old IP address, step 708. The user, MS 11, uses said IP address for transmission of the user traffic within the WLAN network, wherein it has been ensured that the same IP address, being used in the previous network has been provided to the user located in a new network, guaranteeing consequently a continuity in receiving data, which leads to a provision of a seamless handover.

It is to be mentioned, that in case, the query message has been sent after expiry of the delay timer, then the WSN performs an assignment of a new IP address being an embodiment of the second address, as it is known according to the DHCP protocol. Thus, preferably if the answer message 707 is negative, then the WSP generates a new IP address, which is sent to the user by means of the DHCP OFFER message. Of course, this case does not provide a seamless handover.

Moreover, it is to be pointed out, that even though in the above description, an interoperation between CDMA2000 and WLA is described, this should not be seen as a restriction for the present invention, since the same problems also occur in other 3G networks like in UMTS. Although, in UMTS different nodes are implemented, there is a relation in the provided functionality. Thus, for example the functionality implemented in a Serving GPRS Signalling Node (SGSN) and in a Gateway GPRS Signalling Node (GGSN) might be compared with the functionality of the PDSN node in CDMA2000 providing a serving of a user's session in a corresponding serving area. Therefore the solution of the present invention is also applicable to other networks, like for example UMTS.

Thus, although several preferred embodiments of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. Method for providing for a user a seamless handover between a first serving node in a first radio area and a second serving node in a second radio area, wherein a user's data session is identified in the first radio area by means of a first address and wherein an authentification unit being accessible by the first serving node and by the second serving node is provided and wherein said method comprises the following steps being performed in the first serving node,
providing the first address and an address of the first serving node to the authentication node and,
receiving a detach message from the user for detaching from the first serving node,
running a delay timer for delaying a discarding of the first address, wherein a receipt of a request from the second serving node for providing the first address within a duration of the delay timer leads to sending the first address to the second serving node.

2. Method according to claim 1 wherein the first radio area is in a wide area network and the second radio area is in a local area network

3. Method according to claim 2 wherein the first serving node is a node serving a user's data session in its serving area and the second serving node is a local area network gateway.

4. Method according to claim 1 wherein the duration of the timer is predetermined.

5. Method according to claim 1 wherein the receipt of the request from the second serving node for providing the first address leads to sending a non-availability of the first address message to the second serving node if said request is received besides the duration of the delay timer.

6. Method for providing for a user a seamless handover between a first serving node in a first radio area and a second serving node in a second radio area, wherein a user's data session is identified in the first radio area by means of a first address and wherein an authentication unit being accessible by the first serving node and by the second serving node is provided and wherein said method comprises the following steps being performed in the second serving node,
receiving an attach message from the user for attaching to the second serving node and,
sending a request to the authentication unit for providing permission to access a data session and,
receiving as an answer an address of the second serving node from the authentication node and,
sending a request for the first address to the first serving node using the address of the second serving node and,
assigning the first address to the user's data session after receiving the first address.

7. Method according to claim 6 wherein the response from the first serving node provides the first address if the request for the first address has been received by the first serving node within a duration of a delay timer being started on the first serving node.

8. Method according to claim 6 wherein the assignment of the first address to the data session is performed, if the first serving node has responded to the request by providing the first address and if the first address is no available a second address is provided and assigned to the data session.

9. Method according to claim 6 wherein the response from the first serving node provides information about non-availability of the first address.

10. Method for providing for a user a seamless handover between a first serving node in a first radio area and a second serving node in a second radio area, wherein a user's data session is identified in the first radio area by means of a first address and wherein an authentication unit being accessible by the first serving node and by the second serving node is provided and wherein said method comprises the following steps being performed in the authentication unit,
receiving the first address and an address of the first serving node from the first serving node and,
saving the first address and the address of the first serving node and,
receiving a request from the second serving node for providing permission to access a data session and,
sending as a response an address of the first serving node to the second serving node.

11. A first serving node for providing for a user a seamless handover between said first serving node in a first radio area and a second serving node in a second radio area, wherein a user's data session is identified in the first radio area by means of a first address and wherein an authentication unit being accessible by said first serving node and by the second serving node is provided and wherein said first serving node has,
sender unit for providing the first address and an address of said first serving node to the authentication node and,
receiver unit for receiving a detach message from the user for detaching from the first serving node,
delay timer for delaying a discarding of the first address, wherein a receipt of a request from the second serving node for providing the first address within a duration of the delay timer leads to sending the first address to the second serving node.

12. A second serving node for providing for a user a seamless handover between a first serving node in a first radio area and said second serving node in a second radio area, wherein a user's data session is identified in the first radio area by means of a first address and wherein an authentication unit being accessible by the first serving node and by the second serving node is provided and wherein said second serving node comprises,
a first receiver unit for receiving an attach message from the user for attaching to the second serving node and,
a first sender unit for sending a request to the authentication unit for providing permission to access a data session and,
a second receiver unit for receiving an address of the second serving node from the authentication node and,
a second sender unit for sending a request for the first address to the first serving node using the address of the second serving node and,
assignment unit for assigning the first address to the data session.

13. The second serving node according to claim 12 wherein the assignment unit for assigning an address to the data session assigns a first address if the first serving node has responded to the request by providing the first address or if the first address is no available second address is provided and assigned to the data session.

14. The second serving node according to claim 12 wherein the first and the second sender are realised physically and logically as one unit and/or wherein the first and the second receiver are realised physically and logically as one unit.

15. An authentication unit for providing for a user a seamless handover between a first serving node in a first radio area and a second serving node in a second radio area, wherein a user's data session is identified in the first radio area by means of a first address and wherein said authentication unit being accessible by the first serving node and by the second serving node is provided and wherein said authentication unit comprises,
a first receiver unit for receiving the first address and an address of the first serving node from the first serving node and,
a storage unit for saving the first address and the address of the first serving node and,
a second receiver unit for receiving a request from the second serving node providing permission to access a data session and,
a sender unit for sending the second address and the address of the first serving node to the second serving node.

16. A network part for providing for a user a seamless handover between a first serving node in a first radio area and a second serving node in a second radio area, wherein a user's data session is identified in the first radio area by means of a first address and wherein an authentication unit being accessible by the first serving node and by the second serving node is provided and wherein said network part with,
the first serving node
sending the first address and an address of the first serving node to the authentication node for storing said addresses and
running a delay timer for delaying a discarding of the first address by receiving a detach message from the user for detaching from the first serving node
the second serving node
sending a request to the authentication unit for providing permission to access a data session after receiving an attach message from the user for attaching to the second serving node, and
receiving an address of the second serving node from the authentication node as an answer, and
sending a request for the first address to the first serving node using the address of the second serving node, and
receiving and assigning the first address to the user's data session, if the first serving node has responded to the request by providing the first address or assigning a second address to the data session, if the first address is no available.
